(19) United States
(12) Patent Application Publication
(10) Pub. No.: US 2022/0237345 A1
(43) Pub. Date: Jul. 28, 2022

(54) COMPUTING SYSTEM FOR IMPLEMENTING AND OPERATING MODEL DESCRIBING TARGET SYSTEM, AND METHOD OF PREDICTING BEHAVIOR OF TARGET SYSTEM USING THE SAME

(71) Applicants: EINS S&C CO., LTD, Jeju-si (KR); KOREA DIGITAL TWIN LAB. INC., Daejeon (KR)

(72) Inventors: Young Jin YANG, Jeju-si (KR); Tag Gon KIM, Daejeon (KR); Ho Dong YOO, Daejeon (KR)

(21) Appl. No.: 17/722,268

(22) Filed: Apr. 15, 2022

Related U.S. Application Data
(63) Continuation of application No. PCT/KR2020/014202, filed on Oct. 16, 2020.

(30) Foreign Application Priority Data
Oct. 16, 2019 (KR) 10-2019-0128487
Oct. 16, 2019 (KR) 10-2019-0128672

(51) Int. Cl. G06F 30/20

(52) U.S. Cl. CPC G06F 30/20

(57) ABSTRACT

Disclosed herein is a computing system for implementing and operating a system model describing a target system, the computer system comprises a processor configured to select first data as input data of a first sub-module, based on structural information, from among new input data for the target system, provide second data as input data of a second sub-module, based on the structural information, wherein the second sub-module is defined to receive output data of the first sub-module as input data thereof by the structural information, control the second sub-model to infer a behavior of the target system based on the second data, and provide third data based on output data of the second sub-module as an output of the system model describing the behavior of the target system.

### CROSS-REFERENCE TO RELATED APPLICATION

This application is a Continuation of International Application No. PCT/KR2020/014202 filed on Oct. 16, 2020, which claims priority to Korean Application No. 10-2019-0128487 filed on Oct. 16, 2019, and Korean Application No. 10-2019-0128672 filed on Oct. 16, 2019. The aforementioned applications are incorporated herein by reference in their entireties.

### TECHNICAL FIELD

The present invention relates to technology for modeling and simulating a physical complex system, and more particularly to technology for implementing and operating digital model describing target system using computing system. Further, the present invention relates to technology for elaborating the digital model by using the theory-based model and the data-driven model due to data analytics together with regard to the implementing and operating the digital model.

### RELATED ART

Demands for improvement in productivity, economic efficiency, and safety in the industrial field are spreading. Recently, technologies such as the Internet of Things (IoT), big data, artificial intelligence, and cyber physical systems (CPS) have been widely used. As a technology trend into which these technologies are integrated, digital twin technology is attracting attention.

A digital twin is a digital replica(twin) of a physical object (an asset, a process, a system, or the like), and may be a virtual model that maintains the properties/states of target object elements throughout their lifecycle and describes dynamic nature regarding how they behave.

Digital twins implemented in computing systems are used in the industrial field for various purposes, such as predicting a situation that may occur in reality or informing a condition for optimizing operation while reflecting a real situation in conjunction with a target object (a physical asset), and are recognized as a means for enhancing competitiveness.

The Internet of Things (IoT) technology and digital twin technology are closely related with each other. The advancement of IoT platform technology enables smart services such as machine learning/artificial intelligence (AI)-based prediction, failure diagnosis, optimization, and predictive diagnosis after the collection of the sensor data of an operating system in real time. Digital twin technology was started on the assumption that it was used in the industrial field, but recently, efforts are being made to expand its application areas to more diverse smart services, such as a cyber city. It is substantially impossible to mount all sensors for collecting all data required for various smart services in an operating system due to physical constraints (the locations and number of sensors) and/or economic constraints (the number of sensors).

As a means for partially solving this problem, U.S. Patent Application Publication No. 2017/0286572 entitled “Digital Twin of Twinned Physical System” discloses a technology that simulates the operation/behavior of a real sensor by using a digital twin of the real sensor, and, when the real sensor stops working, collects data from a virtual sensor corresponding to the real sensor in a digital twin model and replaces the operation of the real sensor.

Korean Patent Application Publication No. 10-2019-0013610 entitled “System, Method, and Control Unit for Controlling the Operation of a Technical System” discloses a technology that generates virtual sensor data using a digital twin of a real sensor and replaces the abnormal real sensor with the virtual sensor data when an abnormality of the real sensor is detected.

U.S. Patent Application Publication No. 2019/0068618 entitled “Using Virtual Sensors to Accommodate Industrial Asset Control Systems during Cyber Attacks” discloses a technology that simulates a digital twin model for a normal case and a cyberattack case and dynamically replaces an attacked one of real sensors with a virtual sensor when a system is actually attacked.

In general, in order to analyze and/or predict operation, behavior, and performance on a system in the real world, an abstract model of the system is generated and executed, to measure/observe the operation, behavior, and performance. In order to secure the reliability of the analysis/prediction results of the target system through these models, the important key is how well (accurately) the system is modeled.

As one modeling method, there is a method of making an abstract model using knowledge such as physical laws or operation/behavioral rules included in a target system, which is a modeling and simulation (M&S)-driven method that may express a causal relationship between the controlled input and the corresponding output as a model. This method has a limitation that detailed information about the system to be modeled needs to be available. In addition, when a model is built by the M&S-driven method, it is essential to perform a process of verifying how well the model reflects the real system with real data to ensure validity of the model. When it is difficult to obtain data from the real-world system, the validity of the model cannot be checked, and as a result, a problem that the reliability of the model-driven analysis/prediction results cannot be guaranteed may arise.

As another modeling method for prediction and analysis of a system, there is a data modeling method in the form of deriving rules/patterns/functions contained in the system by analyzing a large amount of data acquired through operation and observation of the target system. A machine-learning-driven model, which may be said to be a representative method of data modeling, is a method that shows a correlation between one set of data and another set of data. In the era of big data, more effective machine learning has become possible by using large amounts of data. However, while the data model built by the machine learning may be predicted on the premise that the system will operate without any changes in the future, when the system configuration or behavioral rules change, there is a limitation in that the future may not be predicted with a previously trained model.

The term “big data” is widely used for a means of making predictions about a diversified society. “Big data” refers to datasets of sizes beyond the ability of typical software tools to collect, manage, and process within an allowable passage of time. Since such large-capacity data provides more insight than existing limited data, big data is receiving much attention in research in various fields such as science, engineering, national defense, management, medicine, and politics. For this reason, modeling using big data is becoming an essential and important issue in the era of big data.

A model created based on a physical law or an operation/behavioral rule is called a physics-driven model, and a model that analyzes data and derives a rule hidden in the data is called a data-driven model. A physical-driven model has the advantage that its field of application can be extended without being limited to actual measurement data, but has the disadvantage in that verification with actual measurement data is required, while with a data-driven model, verification with actual measurement data is performed first in the analysis process, but it has a limitation that it may not be applied to a range out of the actual measurement data. Recently, it has been reported that data-driven models have better performance than physical-driven models due to the development of the artificial neural networks and deep learning techniques, but even if a data-driven model has excellent performance, it still has the limitation that it may not be applied to a range out of the range of the actual measurement data. In addition, a data-driven model may only analyze the correlation between data, and thus has a limitation that it may not explain the causal relationship regarding which data is a cause and which data is a result.

There have been attempts to complement the advantages and disadvantages of these data-driven models and physical-driven models. For example, US Patent Application Publication No. US 2018/0357343 “Optimization Methods for Physical Models” discloses a hybrid model that combines the advantages and disadvantages of a physics-driven model with high fidelity and a data-driven model with low fidelity. In US 2018/0357343, when a calculated competence region of a data-driven model is out of a critical region, the physics-driven model is executed, the physics-driven model is calibrated by expressing a discrepancy between the data-driven model and the physics-driven model in the form of a function, and then a hybrid model combining these relationships is used. In this case, the competence of the data-driven model is calculated based on the accuracy of the sample data of the data-driven model.

In the case of a single system in which the input data and output data of the target system are clearly defined, the hybrid model combining the advantages of the data-driven model and the physics-driven model can be used by application of US 2018/0357343. However, when the target system becomes complex and there are many variables to be dealt with, more advanced data application is required to digitize the target system and implement the target system as the digital twin model.

### SUMMARY

In the prior art and the above-described preceding art, a behavior or state of the real world is simulated by being simplified into a single model. In this case, the use of the hybrid model that combines the physical-driven model capable of deductive reasoning and the data-driven model based on data training is disclosed by the prior document US 2018/0357343, but since the target system in the real world is very complex, it is not easy to identify the operation, behavior, or state with only a single model.

Also, as target systems to be dealt with become larger and more complex, the limits of attempts to describe the target system with a single model are being revealed.

The present invention is devised to solve the problems of the related art, and may provide a system model capable of modeling a causal relationship between multiple causes and results that describe a target system, and integrally describing the entire target system by combining sub-models that partially describe the target system. In this case, a combining relationship and/or a data connection relationship between sub-models in the system model is defined based on structural information, and the structural information may be acquired using knowledge about the target system.

The present invention may provide a hybrid model that operates by combining the advantages of a physical-driven model and a data-driven model, and provides a system modeling technique capable of applying a hybrid model to a system model described by a complex model by extending a field of application of the hybrid model.

The present invention may provide a cooperative, not competing with each other, alternative capable of overcoming limitations of each approach by complementarily utilizing advantages of two modeling methods, a physical-driven model and a data-driven model, to enable robust analysis/prediction support. In this case, unlike the related arts in which the physical-driven model or the data-driven model is selectively applied, the present invention may provide a technique capable of implementing a complex model by combining the physical-driven model and the data-driven model more robustly.

The present invention may provide a system model capable of using accuracy of a data-driven model, but inferring data out of a data range which is a limitation of the data-driven model.

The present invention may provide a system model capable of describing a behavior or state of a target system due to complex causes using a data-driven model, and that generates descriptive information that may explain a correlation between data in a data-driven model based on structural information.

The present invention may provide a system model capable of applying normative analysis using a data-driven model, which was difficult to implement with a data-driven model before.

According to the present invention, a hybrid model that may combine advantages of a data-driven model and a physical-driven model is implemented as a complex system model, and the complex system model may be applied to a digital twin for describing a highly complex target system.

The present invention has been conceived to accomplish the above objects. A computing system according to an embodiment of the present invention is a computing system for implementing and operating a model describing a target system, the computing system includes a communication interface configured to receive or require acquired data about the target system; a system model including a plurality of sub-models; and at least one processor. Each of the plurality of sub-models is a model capable of inferring or predicting at least a part of the acquired data as output data when receiving another part of the acquired data as input data, a data connection relation between the input data and the output data of each of the plurality of sub-models in the system model is defined based on structural information of the target system.

The at least one processor is configured to: select first data as input data of a first sub-module, based on the structural information, from among new input data for the target system; provide second data as input data of a second sub-module, based on the structural information, wherein the second sub-module is defined to receive output data of the first sub-module as input data thereof by the structural information; control the second sub-model to infer a behavior of the target system based on the second data; and provide third data based on output data of the second sub-module as an output of the system model describing the behavior of the target system.

The at least one processor may select the second data as the input data of the second sub-module, based on the structural information, among the new input data for the target system.

The at least one processor may control the first sub-model to infer the behavior of the target system based on the first data; and provide the second data using output data from the first sub-module with inference of the first sub-module based on the structural information as the input data of the second sub-module.

Each of the plurality of sub-models may be at least one of a theory-driven model capable of deductive reasoning and is defined based on obtainable domain knowledge, experience, and theory that are related to the target system, a data-driven model trained based on the acquired data about the target system, and a complex model formed by combining the theory-driven model and the data-driven model to be complementary to each other.

The structural information may be defined based on a data connection relation between parameters of a theory-driven primitive model included in the target system and acquired using knowledge about the target system, and whether each of the parameters is included in the acquired data.

The structural information may include information on a first parameter selected as at least one of the input data and the output data of each of the plurality of sub-models from among parameters of a theory-driven primitive model included in the target system and acquired using knowledge about the target system; and sub-model data structure information wherein the first parameter is defined as the input data and output data of each of the plurality of sub-models with respect to the theory-driven primitive model.

The computing system may further include a user interface configured to receive a user query about the target system and transmit the received user query to the at least one processor, and wherein the at least one processor is further configured to interpret the user query into an instruction command that is executed within the computing system.

The at least one processor may search for at least one of a condition variable, a control variable, and a design variable of the target system corresponding to an association of at least two of the first data, the second data, and the third data based on the structural information and the data connection relation when the user query includes a query for the association of at least two or more of the first data, the second data, and the third data, to generate a search result; generate a response to the user query based on the search result; and transmit the response to the user query to the user interface.

When the user query includes a prediction of the behavior of the target system when the second data is out of an acquired data domain covered by the acquired data, the at least one processor is further configured to apply at least one of a theory-driven model capable of deductive reasoning, a data-driven model trained based on the acquired data, and a complex model formed by combining the theory-driven model and the data-driven model to be complementary to each other as the second sub-model.

When the user query includes a request in which a distribution of the third data is to be adjusted, the at least one processor may generate a first distribution applicable to the first data, a second distribution of the second data related to the first distribution, and a third distribution of the third data related to the second distribution among the acquired data based on the structural information and the system model, and provide at least one of a limiting condition of a range of the first distribution in response to the user query based on the first distribution, the second distribution, the third distribution, and the structural information, and a modified condition suggesting a change of at least one of a condition variable, a control variable, or a design variable of the target system to the user.

A computing system according to an embodiment of the present invention includes a communication interface configured to receive or require acquired data about the target system, a system model including a plurality of sub-models, and at least one processor. Each of the plurality of sub-models may be a model trained to infer or predict at least a part of the acquired data as output data when receiving another part of the acquired data as input data. A data connection relation between the input data and the output data of each of the plurality of sub-models in the system model may be defined based on structural information of the target system.

The at least one processor may provide first data for a training of a first sub-module, based on the structural information, from among the acquired data; provide second data for the training of the first sub-module and for a training of second sub-module, based on the structural information, from among the acquired data, wherein the second sub-module is defined to receive output data of the first sub-module as input data thereof by the structural information; and provide third data for the training of the second sub-module, based on the structural information.

The at least one processor may control the first sub-module to learn a relation between the first data and the second data.

The at least one processor may control the second sub-module to learn a relation between the second data and the third data.

A method according to an embodiment of the present invention is the method of operating a system model describing a target system, executed by at least one processor of a computing system implementing and operating the system model, the method comprising: receiving or requiring, by a communication interface, acquired data about the target system; providing, by the at least one processor, first data from among the acquired data as input data of a first sub-model included in the system model, based on structural information; providing, by the at least one processor, second data from among the acquired data as input data of a second sub-model included in the system model, based on the structural information, wherein the second sub-module is defined to receive output data of the first sub-module as input data thereof by the structural information; controlling, by the at least one processor, the second sub-model to infer a behavior of the target system based on the second data; and providing, by the at least one processor, third data based on output data of the second sub-module as an output of the system model describing the behavior of the target system.

A method according to an embodiment of the present invention is the method of training a system model describing a target system, executed by at least one processor of a computing system implementing and operating the system model, the method comprising: receiving or requiring, by a communication interface, acquired data about the target system; providing, by the at least on processor, first data for a training of a first sub-module, based on structural information, from among the acquired data; providing, by the at least on processor, second data for the training of the first sub-module and for a training of second sub-module, based on the structural information, from among the acquired data, wherein the second sub-module is defined to receive output data of the first sub-module as input data thereof by the structural information; and providing, by the at least on processor, third data for the training of the second sub-module, based on the structural information.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplary diagram illustrating a computing system according to an embodiment of the present invention;

FIG. 2 is an exemplary diagram illustrating an embodiment of the system model included in the computing system according to an embodiment of the present invention;

FIG. 3 is an exemplary diagram illustrating an example of a process of deriving structural information used in a computing system according to an embodiment of the present invention;

FIG. 4 is an exemplary diagram illustrating an example of a domain of acquired data used by the computing system according to the embodiment of the present invention and a theoretically extendable data domain;

FIG. 5 is an exemplary diagram illustrating an embodiment of the sub-model included in the system model according to the embodiment of the present invention;

FIG. 6 is an exemplary diagram illustrating the computing system 100 according to the embodiment of the present invention;

FIG. 7 is an exemplary diagram illustrating an example of an operation process of the system model according to the embodiment of the present invention;

FIG. 8 is an exemplary diagram illustrating an embodiment of a theory-driven primitive model on which a system model is based according to an embodiment of the present invention;

FIG. 9 is an exemplary diagram illustrating an embodiment of a system model generated based on the theory-driven primitive model of FIG. 8;

FIG. 10 is an operational flowchart illustrating a method of training a system model executed by a computing system according to the embodiment of the present invention;

FIG. 11 is an operational flowchart illustrating a method executed by the computing system of operating the system model so that the system model infers the behavior of the target system according to the embodiment of the present invention.

FIG. 12 is an exemplary diagram illustrating an example of a process in which the computing system according to the embodiment of the present invention describes a state change of a node in the theory-driven model;

FIG. 13 is a diagram illustrating an example of a target system to which a multi-resolution model is applied as a target system to be described by a system model according to an embodiment of the present invention;

FIG. 14 is a diagram illustrating an example of a case in which traffic flow is described by applying a multi-resolution model as the target system to be described by the system model according to the embodiment of the present invention; and

FIG. 15 is an exemplary diagram illustrating disaggregation transition of data in a transition model and a multi-resolution model to be described by the transition model according to an embodiment of the present invention.

### DETAILED DESCRIPTION

Objects of the present invention other than the above-described objects and the features of the present invention will be apparent from the following description of embodiments to be given with reference to the accompanying drawings.

Embodiments of the present invention will be described in detail below with reference to the accompanying drawings. In the following description of the present invention, when it is determined that a detailed description of a related known component or function may unnecessarily make the gist of the present invention obscure, it will be omitted.

Descriptions of the detailed configurations omitted therein may be replaced by providing notification that the configurations are known to those of ordinary skill in the art via the related art documents, e.g., U.S. Patent Application Publication No. 2017/0286572 entitled “Digital Twin of Twinned Physical System”, Korean Patent Application Publication No. 10-2019-0013610 entitled “System, Method, and Control Unit for Controlling the Operation of a Technical System”, U.S. Patent Application Publication No. 2019/0068618 entitled “Using Virtual Sensors to Accommodate Industrial Asset Control Systems during Cyber Attacks”, and US Patent Application Publication No. US 2018/0357343 “Optimization Methods for Physical Models”, that are cited therein.

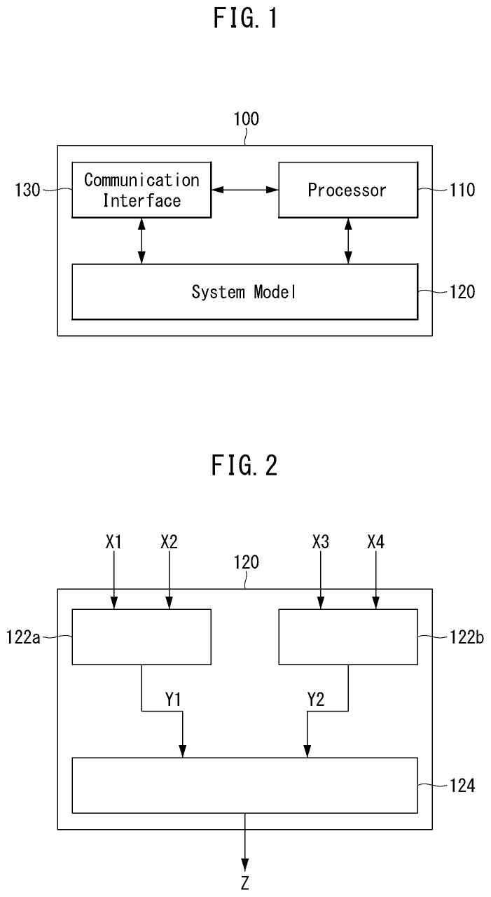

FIG. 1 is a diagram illustrating a computing system 100 according to an embodiment of the present invention.

The computing system 100 includes a system model 120 that describes a target system and may implement and operate the system model 120. Specifically, the computing system 100 includes at least one processor 110, and a communication interface 130 capable of receiving or requiring data acquired from the target system.

The target system is a system in the real world to be analyzed, inferred, and predicted, and may be a system operating according to a physical law or a system operating according to an operation/behavior rule. The laws on which the target system depends are not limited to physical laws, and according to embodiments, the target system may be described with social, psychological, economic rules, or theories. The target system is closely related to the problem to be solved. In the case of analyzing and predicting the spread of forest fires, topography of forests where forest fires may occur, and a distribution of objects such as trees and rocks may constitute the target system. In the case of analyzing and predicting traffic flow, a road network, a signal system, a capacity of each road, vehicles located on a road, and the like may constitute the target system. In this process, in the case of analyzing the traffic flow conditions when an unexpected situation occurs, behavior changes due to human psychological behavior patterns may be added as elements to be identified in the target system. In the case of analyzing and predicting the occurrence, spread, or healing process of diseases, cells, blood vessels, a composition of the skeleton, a composition of organs, blood flow, and the like may constitute the target system.

The target system may also be a large-scale and complex system, such as a digital twin of a smart city. When there are very many variables that affect the target system, it is possible to combine these variables to implement the target system and to abstract the elements to be analyzed. For example, in the case of the smart city, national public data (demographics, maps, etc.) may be collected or utilized, and the collected data may be linked using an IoT infrastructure or the like in the city. The data may be used to simulate a change in behavior of citizens according to a change in policy in the city, and economic activity, floating population activity, or the like according to disasters or geographic environments may be simulated.

The processor 110 may control the system model 120 so that the system model 120 may be trained to learn the data acquired from the target system for the implementation of the system model 120. When the training of the system model 120 is finished and then a new input to the target system is given, the processor 110 may control the system model 120 so that the system model 120 may infer or predict the behavior of the target system based on the new input in order to predict the behavior to be performed by the target system in response to the new input.

The system model 120 may include a theory-driven model and a data-driven model. The data-driven model may include an artificial neural network (ANN). The system model 120 is generally a collective set of data stored in a memory or storage, and the analyzed parameters for the correlation between the acquired data as the training object constitute the system model 120. In the process of the processor 110 controlling the system model 120, the processor 110 accesses the storage or memory in which the system model 120 is stored, and the processor 110 may read the system model 120 and use the read system model 120 for other calculations, or may use the result of the calculation to rewrite some of the parameters of the system model 120.

FIG. 2 is a diagram illustrating an embodiment of the system model 120 included in the computing system 100 according to an embodiment of the present invention.

The system model 120 includes first sub-models 122a and 122b and a second sub-model 124. The first sub-models 122a and 122b may have first data X1, X2, X3, and X4 as inputs and second data Y1 and Y2 as outputs. The second sub-model 124 may have the second data Y1 and Y2 as inputs and third data Z as outputs. The system model 120 may use the third data Z as a final output, but the spirit of the present invention is not limited to the embodiment of FIG. 2.

Each of the plurality of sub-models 122a, 122b, and 124 included in the system model 120 is a model capable of receiving a part of the acquired data and inferring or predicting at least another part of the rest as outputs. Input data and output data of each of the plurality of sub-models 122a, 122b, 124 in the system model 120 may be defined based on structural information of the target system that may be acquired using knowledge about the target system. The structural information includes information on a data connection relationship between the first sub-models 122a, 122b and the second sub-model 124 among the plurality of sub-models 122a, 122b, and 124, and the data connection relationship may include information on whether output data of the first sub-models 122a and 122b may be used for input data of the second sub-model 124.

The first data X1, X2, X3, and X4, the second data Y1 and Y2, and the third data Z are data that may be acquired by being actually measured or observed from the target system. The processor 110 may select the first sub-models 122a and 122b, and the first data X1, X2, X3, and X4, the second data Y1 and Y2, and the third data Z that are suitable for the second sub-model 124 from the actually acquired data of the target system based on the structural information. The selected first data X1, X2, X3, and X4 may be assigned as the input data of the first sub-models 122a and 122b based on the structural information, for training and/or inference of the first sub-models 122a and 122b. The second data Y1 and Y2 may be also assigned as the input data of the second sub-models 124, or output data of the first sub-models 122a and 122b based on the structural information, for training and/or inference of the first sub-models 122a and 122b, and the second sub-model 124. The third data Z may be assigned as the output data of the second sub-model 124 based on the structural information, for training of the second sub-model 124. The processor 110 may provide the first data X1, X2, X3, and X4 as the inputs of the first sub-models 122a and 122b among the acquired data based on the structural information, and provide the second data Y1 and Y2 as the outputs of the first sub-models Y1 and Y2 for training the first sub-models 122a and 122b among the acquired data based on the structural information. The processor 110 may provide the second data Y1 and Y2 as the input of the second sub-model 124 based on the structural information. The processor 110 may control the first sub-model so that the first sub-models 122a and 122b may learn the relationship between the first data X1, X2, X3, and X4 and the second data Y1 and Y2.

In addition, the processor 110 may provide the third data Z among the acquired data as the output of the second sub-model 124 for training the second sub-model 124 based on the structural information. The processor 110 may control the second sub-model 124 so that the second sub-model 124 may learn the relationship between the second data Y1 and Y2 and the third data Z.

In a state in which the first sub-models 122a and 122b and/or the second sub-model 124 are trained, the first sub-models 122a and 122b and/or the second sub-model 124 may infer or predict the behavior of the target system based on the new input data.

In this case, the processor 110 may select new input data as the first data X1, X2, X3, and X4 and provide the first data as the inputs of the first sub-models 122a and 122b. New input data may be acquired by actual measurements, acquired by suggestion or assumption (not actually measured), or acquired by partial measurements. In this case, the data output by the inference or prediction of the first sub-models 122a and 122b may be designated as the second data Y1 and Y2, and the second data Y1 and Y2 may be provided as the input of the second sub-model 124. The process in which the second data Y1 and Y2 output by the inference or prediction of the first sub-models 122a and 122b by the processor 110 is provided as the input of the second sub-model 124 may be executed based on the structural information. In addition, a process of the processor 110 selecting the first data X1, X2, X3, and X4 from new input data may also be executed based on the structural information.

The processor 110 may control the first sub-models 122a and 122b so that the first sub-models 122a and 122b may infer or predict the operation, behavior, state, or state change of the target system based on the first data X1, X2, X3, and X4, and control the second sub-model 124 so that the second sub-model 124 may infer or predict the operation, behavior, state, or state change of the target system based on the second data Y1 and Y2. In this case, FIG. 2 illustrates an embodiment in which the output data of the second sub-model 124 is provided to the user as the final output of the system model 120 as the third data Z. However, according to an embodiment of the present invention, additional calculations may be performed based on the output data of the second sub-model 124, and thus data generated based on the output data of the second sub-model 124 may be provided to a user as the final output of the system model 120.

The processor 110 may provide a part from the new input data as the first data X1, X2, X3, and X4 to the first sub-models 122a and 122b based on the structural information, to cause the first sub-models 122a and 122b, and the second sub-model 124 to generate dataset Y1, Y2, and Z by sequential inferences. The processor 110 may provide a part from the new input data as the first data X1, X2, X3, and X4 to the first sub-models 122a and 122b, and another part from the new input data as the second data Y1 and Y2 to the second sub-model 124 based on the structural information, to cause at least the second sub-model 124 to generate dataset Z by inference. In other words, the second dataset Y1 and Y2 may be assigned from the new input data directly based on the structural information or may be sequentially inferred from the first dataset X1, X2, X3, and X4 based on the structural information.

In this case, each of the plurality of sub-models 122a, 122b, and 124 is defined based on obtainable domain knowledge, experience, and theory that are related to the target system, and may be any of a theory-driven model capable of deductive reasoning or a data-driven model trained based on the acquired data or may be a model in which the theory-driven model and the data-driven model are combined to be complementary. In this case, the data-driven model may be a model using an artificial neural network (ANN). The theory-driven model may be defined by physical laws, rules of behavior, rules of operation, and the like, and the obtainable domain knowledge, experience, and theory may include all the theories based on physics, psychology, economics, and sociology.

Although general data-driven models have recently improved the accuracy of data analysis and prediction through rapid development, there is a problem in that the inside of the data-driven model is treated as a black box and thus it is difficult for humans to understand the internal operation. Therefore, the accurate prediction is only possible within the actually acquired data domain, and it is difficult to accurately predict an input out of the data domain. Meanwhile, in general theory-driven models, descriptive/deductive reasoning is possible and inferences are possible even for inputs that are out of a predetermined domain, but it is necessary to verify whether real data is applied to predict what will happen in the real system.

The system model 120 according to an embodiment of the present invention may combine the data-driven model and the theory-driven model to be complementary, a large frame may be configured like the theory-driven model using the structural information, and each of the sub-models 122a, 122b, and 124 may be configured as the data-driven model. In this case, since the entire structure of the system model 120 is obtained by knowledge, theory, or experience, explanatory/deductive reasoning is possible, and inference is also possible for an input out of a predetermined domain. Meanwhile, when each sub-model 122a, 122b, and 124 is the data-driven model, since each sub-model 122a, 122b, and 124 is a model already obtained based on data in the acquired data domain, additional verification with actual measurement data is not required.

In addition, in the embodiment of the present invention, all the sub-models 122a, 122b, and 124 may be composed of the theory-driven model, or some of the sub-models 122a, 122b, and 124 may be composed of the theory-driven model and the rest may be composed of the data-driven model. When all the sub-models 122a, 122b, and 124 are composed of the theory-driven model, a case where each of the sub-models 122a, 122b, and 124 is verified with actual measurement data and exhibits the same accuracy as the data-driven model may be considered.

For example, in the system model 120 of FIG. 2, it may be assumed that only a specific sub-model 122a is the data-driven model, and in the other sub-models 122b and 124, the theory-driven model may predict the actual target system with accuracy comparable to that of the data-driven model. In this case, the specific sub-model 122a is valid only within the domain of the given acquired data, but the other sub-models 122b and 124 are operable in an extended range outside the domain of the acquired data. In this system model 120, when the user wants to predict the operation/behavior of the target system in the case where the user inputs X3 and X4 of the input data out of the existing range, a solution that satisfies the user's needs may be provided.

In other words, when the target system may be modeled to a large extent with the theory-driven model, in the case where the performance of the data-driven model is superior to that of the theory-driven model only for the specific sub-model 122a, the data-driven model may be used as the specific sub-model 122a, and the rest of the system model 120 may use the theory-driven model.

In general, the data-driven model is known to have strengths in a predictive analysis that analyzes “what will happen?” based on a descriptive analysis that analyzes “what happened?” but is known to have difficulty supporting normative analysis that analyzes “how did the event happen?” “how do I get the desired result?” or the like.

The system model 120 according to the embodiment of the present invention complementarily combines the data-driven model and the theory-driven model to support the normative analysis using the structural information based on a theory while using the data-driven model.

In the above example, since the specific sub-model 122a is a black box, the behavioral/operation rule of the specific sub-model 122a may not be changed, but the behavioral/operation rules of the other sub-models 122b and 124 may be changed. Also, it is not possible to change the internal behavioral/operation rule of the specific sub-model 122a, but by changing the behavioral/operation rules of the other sub-models 122b and 124 in the vicinity connected to the specific sub-model 122a, within the entire system model 120, the specific sub-model 122a may be treated as if the relative behavioral/operation rules are changed. Since it is possible to change the relative behavioral/operation rules within the system model 120, the system model 120 may perform the normative analysis (including control policy, etc.) from the predictive analysis, and cognitive analysis (including planning, etc.) from the normative analysis.

If a single data-driven model is treated as a black box, the theory-driven model may be considered as a white box, and the model in which the data-driven model and the theory-driven model are combined may be considered as a gray box. In this case, when only the input and output of the data-driven model are observed in connection, the corresponding sub-model block may be considered as a black box, but from the point of view of the entire system model 120, in the data domain, the system behavior/operation may be completely reproduced by other theory-driven models in the vicinity, including the input and output data of the data-driven model.

Also, according to the embodiment of the present invention, the theory-driven model and the data-driven model may be used together in one sub-model. For example, there may be a case where the theory-driven model presents a mathematical relational expression, but does not accurately inform of coefficients or orders of the relational expression. In this case, the coefficients or orders of the theory-driven model may be obtained by the data-based learning.

For convenience of description, as a simple example, it is assumed that the first sub-models 122a and 122b are the data-driven models, and the second sub-model 124 is the theory-driven model. It may be noted that the second sub-model 124, which is the theory-driven model, may be described as a simple linear relational expression of Z=mYl+nY2. However, it is assumed that values of coefficients m and n may not be known only by theory. In this case, in order to obtain m and n, the coefficients m and n may be obtained by the data-based learning between Y1, Y2, and Z.

That is, one sub-model may be modeled as the data-driven model, or the one sub-model may be a theory-driven model while its coefficients or orders are specified by the data-based learning. In addition, when the theoretical basis is clear, the theory-driven model may be implemented as a highly definitive mathematical model.

There may be various types of sub-models described above. The system model 120 of the present invention is differentiated from the related art in that the structure of the entire system model 120 is determined based on the structural information. Based on this structural information, each sub-model is connected, and even when each sub-model corresponds to a black box, the other sub-models connected to the sub model completely reproduce the system behavior/operation using the input and output of the black box, and thus the system model 120 may provide a result such as a white box to the user based on the structural information. The characteristic of the system model 120 of operating like the white box provides a platform that may provide a user with descriptive information on a correlation between data inside the system model 120 even when the data-driven model is used as the sub-model.

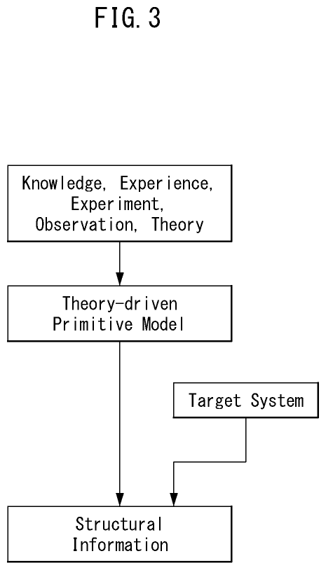

FIG. 3 is a diagram illustrating an example of a process of deriving structural information used in a computing system according to an embodiment of the present invention.

The structural information defining the internal structure of the system model 120 may be obtained based on a theory-driven primitive model that may be acquired using the knowledge about the target system. The theory-driven primitive model may be derived based on a data connection relationship and a causal relationship between parameters in the target system. It is identified whether each of the various parameters included in the theory-driven primitive model may be included in the acquired data, that is, whether each of the various parameters is actually a measured or observed parameter for the target system, and the identified information of each parameter is derived as the structural information for the target system.

The structural information may be derived through the process of deriving a theory-driven primitive model from knowledge, experience, experiment, observation, theory, etc., and identifying data that may be obtained from the target system. This process may be executed by the computing system 100 or a separate computing system, or may be executed by interaction with the computing system 100 through human intervention in some processes.

For example, in the state in which the establishing of the theory-driven primitive model is executed by human behavior, it may be identified by the computing system whether each of the parameters constituting each node of the theory-driven primitive model corresponds to data that may be actually obtained from the target system.

In this case, the structural information may include information on related parameters that may be selected as input data or output data of each of the plurality of sub-models among parameters in the target system constituting the theory-driven primitive model that may be acquired using the knowledge about the target system, and each of the related parameters includes the sub-model data structure information defined as the input data and output data of each of the plurality of sub-models based on the theory-driven primitive model.

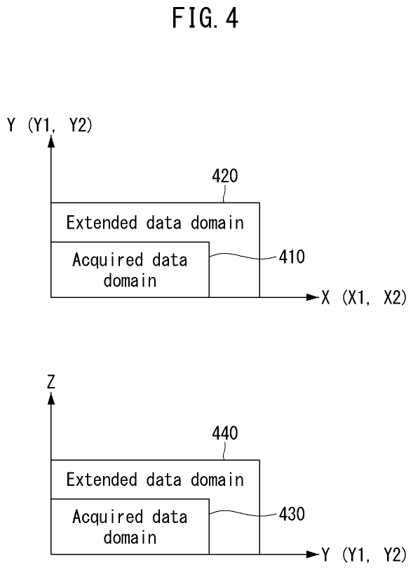

FIG. 4 is a diagram illustrating an example of a domain of acquired data used by the computing system according to the embodiment of the present invention and a theoretically extendable data domain.

When the first data X1, X2, X3, and X4 is obtained from the actually acquired data, a distribution of the second data Y1 and Y2 appearing in the same time variant or space variant as the first data X1, X2, X3, and X4 is shown in an acquired data domain 410. Meanwhile, the distribution of the third data Z appearing in the same time variant or space variant as the second data Y1 and Y2 obtained from the actually acquired data is also shown in an acquired data domain 430.

For the purpose of establishing the design or plan of the system model 120, data beyond the acquired data domains 410 and 430 may be provided to the system model 120 as input. For example, when the first data X1, X2, X3, and X4 is outside the acquired data domain 410, the system model 120 infers the behavior/operation of the target system based on the first data X1, X2, X3, and X4 outside the acquired data domain 410, and the distribution of the second data Y1 and Y2 appearing at this time may constitute the extended/extendable data domain 420.

Similarly, the system model 120 infers the behavior/operation of the target system based on the second data Y1 and Y2 outside the acquired data domain 430, and the distribution of the third data Z appearing at this time may constitute the extended/extendable data domain 440.

The system model 120 of the present invention may maximally use the accuracy of the data-driven model, but may infer or predict the behavior/operation of the target system even for data out of the acquired data domains 410 and 430, which is a limitation of the data-driven model.

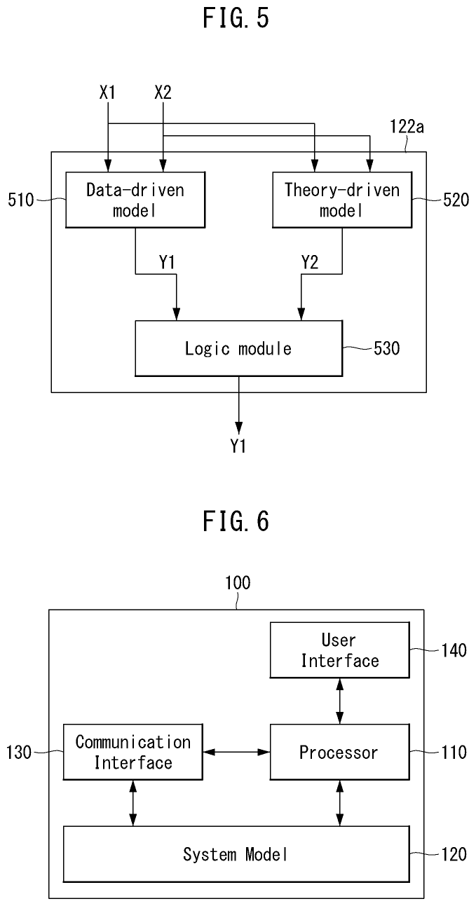

FIG. 5 is a diagram illustrating an embodiment of the sub-model 122a included in the system model 120 according to the embodiment of the present invention.

The sub-model 122a of FIG. 5 includes a data-driven model 510 and a theory-driven model 520 therein, and a logic module 530 selects any one output between the data-driven model 510 and the theory-driven model 520, or combines the outputs of the data-driven model 510 and the theory-driven model 520 to generate the output of the sub-model 122a.

According to the embodiment of the present invention, the data-driven model 510 and the theory-driven model 520 may be competitively combined. For example, when input data within the range of the actual acquired data is given, the logic (or logical operation) module 530 may be designed to select any one between the data-driven model 510 and the theory-driven model 520 based on the prediction accuracy of each of the data-driven model 510 and the theory-driven model 520.

According to the embodiment of the present invention, the data-driven model 510 and the theory-driven model 520 may be complementarily combined. Based on whether the input data X1 and X2 given in FIG. 5 is out of the acquired data domain 410, the logic module 530 may select which one of the data-driven model 510 and the theory-driven model 520 is to be applied. For example, within the acquired data domain 410, the data-driven model 510 may be applied, and the theory-driven model 520 may be applied to the input data out of the acquired data domain 410.

In order for the theory-driven model 520 to be applied in the extended data domain 420, a process for enhancing the correlation/consistency between the theory-driven model 520 and the data-driven model 510 within the acquired data domain 410 may be required. Such a process may be, for example, in the form of curve fitting or the like for coefficients or orders of the theory-driven model 520. In order to improve the consistency between the theory-driven model 520 and the data-driven model 510, a separate hybrid model having a form similar to the system model 120 of FIG. 2 may be applied.

Referring to FIGS. 4 and 5 together, an attempt to extend data to the extended data domains 420 and 440 is particularly meaningful when, for example, the distribution of data in the acquired data domains 410 and 430 is qualitatively asymmetric. In the case of a system model implemented using factory equipment as a target system, normal operation data will be significantly more than abnormal operation data. Therefore, when training is performed using data in an asymmetric state, there is a possibility that the system model may be trained while being overfitted to the normal operation data. In addition, since it is not easy to acquire the abnormal operation data in an actual situation, the distribution of the asymmetrical data may be compensated for somewhat by extending data assuming a virtual situation.

The extension of data is necessary to secure a balanced distribution of data when predicting the future behavior/operation from the current behavior/operation of the target system. In addition, the analysis and prediction of the system model for the extended data domains 420 and 440 even in the case of design changes and planning for improvement of reliability, stability, quality, or performance of the target system as well as the normal/abnormal operation is required.

FIG. 6 is a diagram illustrating the computing system 100 according to the embodiment of the present invention. Referring to FIG. 6, the computing system 100 may further include a user interface 140 to easily implement a service model interacting with a user.

The computing system 100 further includes the user interface 140 for receiving and transmitting a user query regarding the target system to at least one processor 110, and at least one processor 110 may interpret the user query and convert the user query into an instruction command that may be executed in the computing system 100.

In response to the user query, the processor 110 may interpret and express the behavior/operation and state of the target system so that the user may easily understand it based on the structural information.

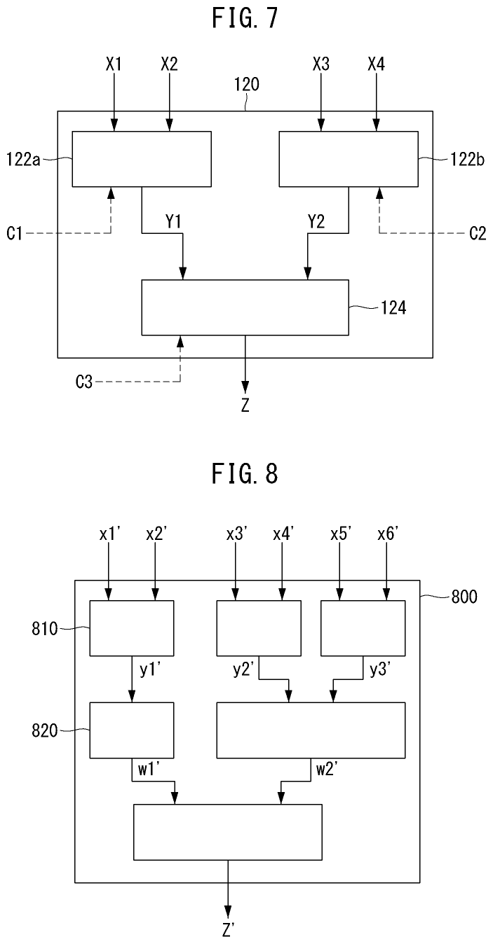

FIG. 7 is a diagram illustrating an example of an operation process of the system model 120 according to the embodiment of the present invention.

Referring to FIG. 7, the sub-model 122a has a conditional variable C1, the sub-model 122b has a conditional variable C2, and the sub-model 124 has a conditional variable C3. C1, C2, and C3 may be condition variables, control variables, or design variables. Even when each of the sub-models 122a, 122b, and 124 is the data-driven model, the condition variable reflected in the process of combining the sub-models 122a, 122b, and 124 with other sub-models in the system model 120 may be determined based on the structural information.

When there is a user query, the processor 110 may generate proposals for normative analysis, planning, and design optimization for the target system using the structural information and the condition variables/control variables/design variables C1, C2, and C3 for the user query.

When the user query includes a query for the correlation of at least two or more of the first data X1, X2, X3, and X4, the second data Y1 and Y2, and the third data Z, at least one processor 110 may search for at least one of the condition variable, the control variable, or the design variable of the target system corresponding to the correlation of at least two or more of the first data X1, X2, X3, and X4, the second data Y1 and Y2, and the third data Z based on the structural information and the data connection relationship of the sub-models 122a, 122b, and 124 and generate the corresponding search result, generate a response to the user query based on the corresponding search result, and transmit the response to the user query to the user interface 140.

For example, when all of the sub-models 122a, 122b, and 124 are the data-driven models, in the case where the user query includes a process of deriving the result of the prediction of the third data Z by the system model 120 from the first data X1, X2, X3, and X4, the processor 110 may provide descriptive information about the system model 120 describing the target system based on the connection relationship between the second data Y1 and Y2 and the sub-models 122a, 122b, and 124 that are intermediate results that are not directly revealed in the system model 120. In addition, the processor 110 may verify the validity, reliability, and stability of the descriptive information based on the actual measurement data of the second data Y1 and Y2 which is the intermediate results.

When the user query includes a prediction of the behavior/operation of the target system for the case (intended harsh environment or unknown operation conditions) where the first data X1, X2, X3, and X4 is outside the acquired data domain 410 covered by the acquired data, at least one processor 110 may input the first data X1, X2, X3, and X4 to the first sub-models 122a and 122b to control the first sub-models 122a and 122b to predict the behavior/operation of the target system in response to the first data X1, X2, X3, and X4. At least one processor 110 may apply one of the theory-driven model capable of deductive reasoning as the first sub-models 122a and 122b or the data-driven model trained based on the acquired data, or combine the theory-driven model and the data-driven model to be complementary and apply the combination to the first sub-models 122a and 122b.

When the user query includes the condition in which the distribution of the third data Z is adjusted (which may include an intention to improve the reliability, stability, performance, and quality of the target system), at least one processor 110 may generate a first distribution of data applicable to the first data X1, X2, X3, and X4 among the acquired data, a second distribution of the second data Y1 and Y2 related to the first distribution, and a third distribution of the third data Z related to the second distribution, based on the structural information and the system model 120. In this case, it is assumed that the characteristic information indicated by the distribution of the third data Z within the acquired data domain 430 may be evaluated as indexes of the stability, reliability, quality, performance, etc., of the target system. In this process, for example, it may be understood that a set of condition variables {C1, C2, C3} varies and inference/prediction is repeated to secure simulation results corresponding to the set of various condition variables {C1, C2, C3}. Alternatively, the processor 110 may analyze the relationship between the real distribution of each piece of the acquired data and the target distribution of data representing the desired quality or performance, and may generate a proposal for changing the set of condition variables {C1, C2, C3} for deriving the target distribution from the real distribution. In this way, at least one processor 110 may provide a limiting condition of a range of the first distribution in response to the user query based on the first distribution, the second distribution, the third distribution, and the structural information or provide a possibility of changing at least one of a condition variable, a control variable, or a design variable of the target system to the user.

For example, in the acquired data domains 410 and 430 in FIG. 4, the data is uniformly distributed in the real distribution. When data needs to be more concentrated in the center of the acquired data domains 410 and 430 in order to improve the stability and reliability of the target system or to improve the quality and performance of the final output, the target distribution may be set according to these needs. In this case, the user query may include complex needs. For example, the complex needs to improve the quality and performance of the final output without degrading the stability and reliability of the target system may be converted into a target distribution and set. The processor 110 may adjust the structural information and condition variables C1, C2, C3 in the system model 120 in order to obtain the target distribution in the given real distribution, or may generate a proposal to limit the range of input data.

FIG. 8 is a diagram illustrating an embodiment of a theory-driven primitive model 800 on which a system model is based according to an embodiment of the present invention.

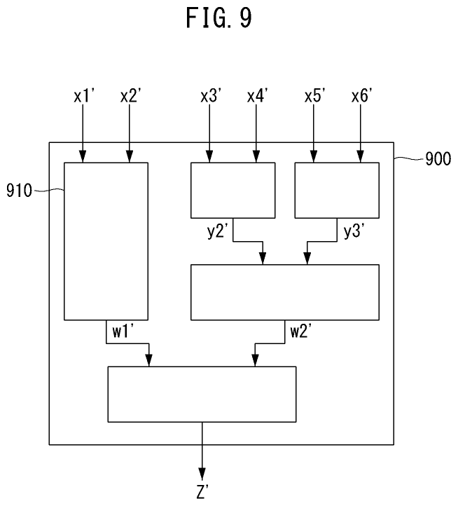

FIG. 9 is a diagram illustrating an embodiment of a system model 900 generated based on the theory-driven primitive model 800 of FIG. 8.

For the system modeling, a hypothetical model for the target system may be defined in the form of a gray box by first identifying the domain knowledge/experience, the theory, and the like related to the target system. Since it is difficult to perform the simulation with the hypothetical model itself, a process of constructing a complete model by securing information such as motion functions and parameters necessary for model completion is required. For the information necessary to complete the model, big data is acquired by actually operating/observing the target system, and information necessary to generate the theory-driven primitive model 800 is acquired using the hypothetical model through machine learning on the acquired big data. By learning big data acquired through the actual behavior/operation and observation of the target system using a machine learning algorithm such as an artificial neural network, the information necessary for the theory-driven primitive model 800 may be learned. The theory-driven primitive model 800 for the target system is generated by applying the learned and verified information based on the actual data to the hypothetical model.

The theory-driven primitive model 800 is implemented to have the structural information through a plurality of parameters that may appear in the target system. In this case, on the premise that each parameter is secured, the theory-driven primitive model 800 corresponds to a white box. However, since not all parameters may actually be measured or observed from the target system, editing is required to implement the parameters as the system model 900.

It is assumed that y1′ among the parameters in FIG. 8 is a parameter that may not be actually measured or observed. The sub-models 810 and 820 related to the parameter y1′ may not be applied to the system model 900 without change, and need modification to be applied to the system model 900.

As illustrated in FIG. 9, the sub-models 810 and 820 related to the parameter y1′ may be merged into one sub-model 910 and included in the system model 900. In this case, it is assumed that all of x1′, x2′, and w1′ can be actually measured or observed from the target system.

Since only the parameters that may be actually measured or observed from the target system are set as main nodes of the system model 900, the sub-models of the system model 900 may be implemented as the data-driven model or the theory-driven model. In this case, since the structural information includes information on the connection relationship and the coupling relationship between the sub-models in the system model 900, the structural information may be involved in the behavior/operation of each sub-model as the semantics of the system model 900.

In an embodiment of the present invention, the sub-models may be partially data-driven models, and all the sub-models may be configured as data-driven models. However, since the connection relationship of each sub-model, that is, the internal structure of the system model 900, is given by the structural information, the system model 900 may perform the normative analysis while using the data-driven model, provide the descriptive information, and support the design change and planning. If all of the parameters displayed in FIG. 9 are data that may not be actually obtained from the target system, the system model 900 of FIG. 9 will be treated as one black box, so in this case, it should be interpreted that the present invention is not applied.

The structural information of the present invention is set based on observation data required for each sub-model to learn by treating the behavior of the sub-models inside the system model 900 as a black box. When there is no observation data of the parameters inside the system model 900, the learning is impossible, and when there is no learning data, the internal behavior of the system model 900 may not be identified.

It does not matter whether collected data x1′, x2′, x3′, x4′, x5′, x6′, y2′, y3′, w1′, w2′, and z′ can be input variable values, output variable values, or state variable values, and it is only important whether the collected data is values that may be actually measured or observed by a sensor.

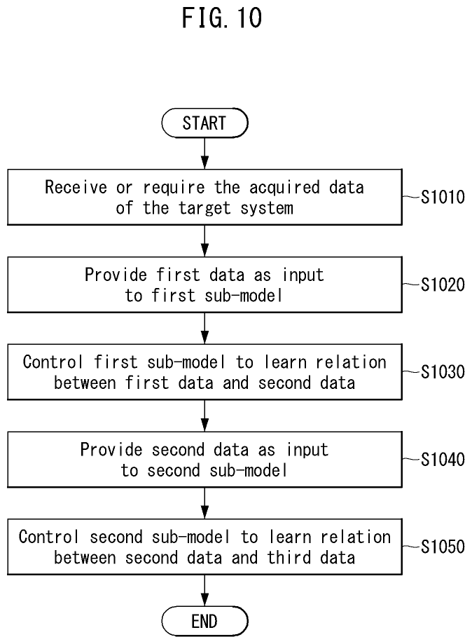

FIG. 10 is an operational flowchart illustrating a method of training a system model 120 executed by a computing system 100 according to the embodiment of the present invention.

A method of operating a system model 120 executed by a computing system 100 according to an embodiment of the present invention, and a method of training a system model 120 are executed by the system model 120 including the plurality of sub-models 122a, 122b, and 124 and the computing system 100 including at least one processor 110.

According to an embodiment of the present invention, a method of training a system model 120 executed by a computing system 100 implementing and operating a system model 120 describing a target system includes receiving or requiring, by the communication interface 130, the acquired data (S1010), providing, by at least one processor 110, the first data X1, X2, X3, and X4 of the acquired data as inputs to the first sub-models 122a and 122b (1020), providing, by at least one processor 110, the second data Y1 and Y2 defined as outputs of the first sub-models 122a and 122b as the input of the second sub-model 124 based on the structural information (S1040), and controlling, by at least one processor 110, the first sub-models 122a and 122b to learn the relationship between the first data X1, X2, X3, and X4 and the second data Y1 and Y2 (S1030), or controlling the second sub-model 124 to learn the relationship between the third data Z defined as the output of the second sub-model 124 based on the second data Y1 and Y2 and the structural information (S1050). When the first sub-models 122a and 122b are the theory-driven models and need not be trained, step S1030 may be omitted, and when the second sub-model 124 is the theory-driven model and need not be learned, step S1050 may be omitted. However, at least one of the first sub-models 122a and 122b and the second sub-model 1224 is the data-driven model, and therefore at least one of steps S1030 and S1050 is executed by the processor 110.

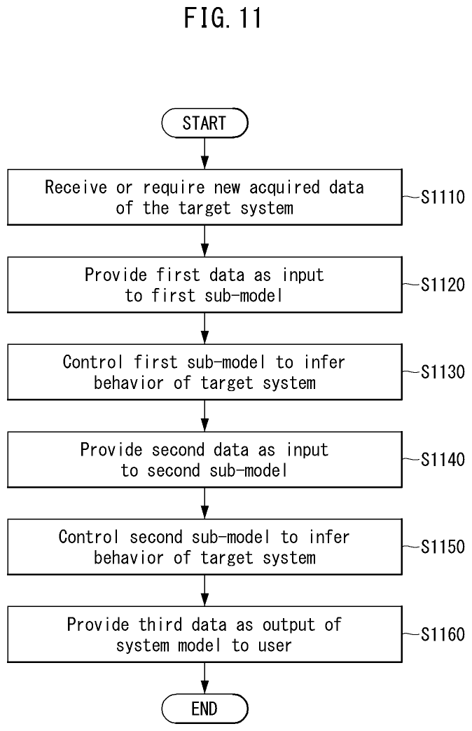

FIG. 11 is an operational flowchart illustrating a method executed by the computing system 100 of operating the system model 120 so that the system model 120 infers the target system according to the embodiment of the present invention.

According to an embodiment of the present invention, a method of operating a system model 120 executed by a computing system 100 implementing and operating a system model 120 describing a target system includes: receiving or requiring, by the communication interface 130, new input data for the target system(S1110); selecting, by at least one processor 110, the first data X1, X2, X3, and X4 from the new input data based on the structural information and providing the selected first data X1, X2, X3, and X4 as the inputs of the first sub-models 122a and 122b(S1120); controlling, by at least one processor 110, the first sub-models 122a and 122b so that the first sub-models 122a and 122b may infer the behavior and/or the operation of the target system based on the first data X1, X2, X3, and X4 (S1130); providing, by at least one processor 110, the output data of the first sub-models 122a and 122b as the second data Y1 and Y2 as the inputs of the second sub-model 124 based on the structural information(S1140); controlling, by at least one processor 110, the second sub-model 124 so that the second sub-model 124 may infer the behavior and/or the operation of the target system based on the second data Y1 and Y2 (S1150); and providing, by at least one processor 110, the third data Z generated based on the output data of the second sub-model 124 or the output data of the second sub-model 124 to the user as the output of the system model 120 (S1160).

In this case, the method of operating a system model 120 of the present invention may further include interpreting, by at least one processor 110, a user query for the target system and converting (not illustrated) the user query into an instruction command that may be executed in the computing system 100.

The present invention may have the following advantages compared to the existing data-driven model. In general, the data-driven model shows very high accuracy for static data, but it is known that it is not easy to apply the data-driven model to dynamic analysis where variables that affect the operation are various. A system model that describes a complex real-world target system represents how the internal variables (state variables) of the target system change over time. It is defined as a static system when the state (attribute) variable (e.g., it may be expressed in a vector form) of the target system has a constant value (constant) with respect to time, and a system is defined as a dynamic system when the state variable value changes over time.

In general, in the target system, spatial information may be described by being included in the value of the attribute variable (location coordinate) of the target system. Exceptionally, the change in the target system according to the space variant in the target system may be described, and the time variant may be included as the attribute variable of the target system, but for convenience of description, in this specification, a case where the target system is described over time and the spatial information is described as one of the attribute variable values of the target system will be described as a main embodiment.

The data domain may be classified in the way that the target system is classified. A case where a data value is independent of time may be expressed as static data, and a case where the data value varies over time may be expressed as dynamic data. For example, a still image may be classified as static data, and a moving image in which an object in an image moves over time may be classified as dynamic data. Although audio data changes over time, when data is expressed by treating a time axis as attribute information, it may be classified as static data if other attribute information does not change.

The dynamic system includes a target system having a stochastic feature as well as a space variant and a time variant. The conventional theory-driven/physical-driven system model may describe a dynamic system with a space variant, a time variant, and a stochastic feature where theory and physical knowledge allow. However, since the conventional data-driven model includes only mapping information between the input-side data and the output-side data of the model, it is suitable for describing the static system, but has a limitation in not being able to describe the dynamic system. On the other hand, since the system model of the present invention may identify data mapped by each sub-system among data in the data domain based on structural information between internal sub-systems, the system model may classify the target system (dynamic system) with complex variables into a plurality of sub-system models, and may implement some or all of each sub-system model as the data-driven model. That is, the system model of the present invention may establish a system model composed of the data-driven models even for the target system having the stochastic feature as well as the space variant and the time variant.

The existing data-driven model may infer only relatively simple information on the correlation between the input-side data and the output-side data, and cannot easily provide high reliability when the existing data-driven model is used to analyze the dynamic system. However, the system model of the present invention represents the modularized sub-system model as a data model, and the data connection relationship between the sub-system models (expressed as a data model) is defined based on the structural information, and therefore it is possible to provide a platform to which the analysis using the data-driven model may be applied even for the dynamic system.

As an example of the space variant, when the entire system model is expressed based on a cell, a state transition function may not be comprehensively expressed for all cells, but may be expressed differently according to individual cells. Accordingly, the characteristics of the topography that change depending on the location may be reflected for each cell. As an example of the time variant, the state transition function used to describe the system model may be set to be different depending on the time of morning, afternoon, or the like. For example, when there is a morning, afternoon, weekend, holiday, weekday, or specific event in the traffic flow, a system model may be implemented by reflecting seasonal factors. Such variant may be further specified and optimized through the training of the data-driven model.

As an example of the stochastic feature, in the case of the traffic simulation, the fact that a driver's behavior is not always determined but may appear stochastically may be reflected. Since the data-driven model is trained by reflecting only the acquired data, an event may occur with a certain probability under the conditions trained by the data-driven model. In this case, when the situation of the road network changes or a disaster occurs, the change of probability may not be simulated in the pure data-driven model, but in the system model of the present invention, the simulation may be performed by adjusting the stochastic feature based on the data connection relationship in the model and the structural information between the models.

In addition, according to the present invention, it is possible to reflect the non-linear features of the target system. Since many systems in the real world have non-linear features without a superposition theory between input and output, it is a great advantage for a state transition function to be able to consider non-linear features. In addition, additional situation information such as weather conditions may be expressed through data acquired from the real system, and thus the data-driven model may be applied as a modeling technique robust to the implementation of complex digital models such as a digital twin model that mimics the real world.

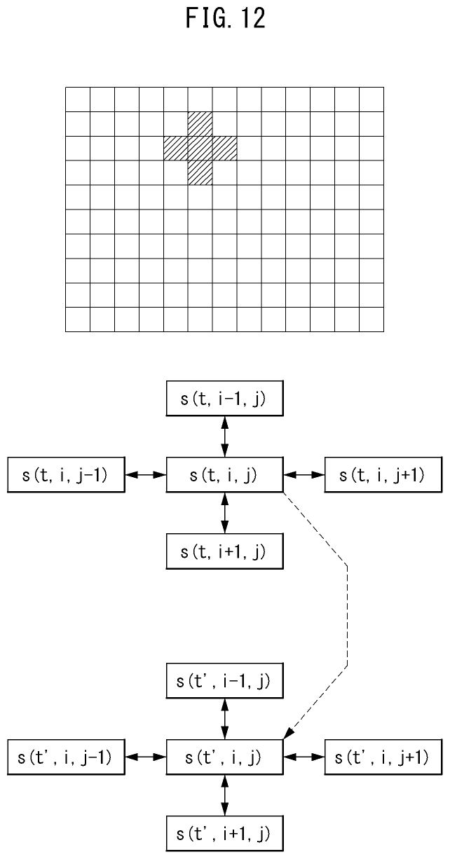

The embodiments of the present invention described in FIGS. 12 to 15 below are examples of the dynamic system to which the present invention may be applied. The dynamic system may describe a traffic flow, a change in weather conditions for a particular (wide or narrow) region, the spread of a disaster such as a fire/forest fire/flood/earthquake (the spread of the damage caused by the disaster), a change in parameters inside a human body based on medical purposes (e.g., a change in blood flow in the heart, blood vessels, etc.), or the like, and the dynamic system is difficult to interpret with a conventional general static system/data-driven model that analyzes static data (e.g., image data).

FIG. 12 is a diagram illustrating an example of a manner in which the computing system according to the embodiment of the present invention describes a state change of a node in the theory-driven model.

The theory-driven model is a model that describes a phenomenon of a target system by deductive reasoning based at least in part on physical laws or behavior/operation rules. The part that may be described as the physical law or the behavior/operation rule is executed by the deductive reasoning, and if necessary, a state of a specific node may be updated by partially applying machine learning.

FIG. 12 exemplarily illustrates a model for dividing the target system into cells according to spatial distribution and updating the state information of each cell over time in order to represent the space variant and the time variant of the target system. A state variable s(i, j) of cell (i, j) may be updated over time. In this case, when described including time t, a state variable may be expressed as s(t, i, j). Each cell may be configured to correspond to one node.

FIG. 12 is an embodiment in which a target system is described using a cell automata technique and illustrates a method of defining a cell automata and updating a state. In addition, the cell automata model may learn a state transition function of each cell through the data-based learning, and the trained state transition function may be provided to the cell automata model.

By using big data collected from the target system, the transition function of each cell may be trained using machine learning such as artificial neural network modeling. The system model 120 described in FIGS. 1 to 11 may be implemented by combining the trained state transition functions and the cell automata model. When the system model 120 described in FIGS. 1 to 11 is applied, the validation problem of the system model 120 as the theory-driven model or simulation model is solved by a cooperative approach, and through the implementation of the system model 120 through the simulation modeling based on the structural information, the improved modeling in which the structure and rules of the target system can be changed is possible.

The cell automata model is a discrete model dealt with in modeling mathematics, physics, complex systems, biology, microstructures, etc., and is defined in cells arranged in a regular grid. Each cell may have a finite number of states, and the grid is defined by a finite number of dimensions. For each cell, neighbors (neighboring cells) are defined by the relationship between the cells, and for example, the neighboring cells may be defined as cells that are spaced one cell away from each other in all directions.

For example, when time t=0, the state of each cell is designated and this is called the initial state. A new generation is created from the previous generation by the state transition function. The conventional state transition function is a mathematical function that specifies a new state of each cell and its neighbors according to the states of its neighbors, that is, determines the behavioral rules of cells.

In general, the above behavioral rules are the same for each cell, do not change over time, and are applied simultaneously to all cells of each generation. The state transition is the process of transitioning from s(t, i, j) to s(t′, i, j), and the state transition at this time may be represented by a state transition function T. The state of each cell may be defined according to the type of problem such as traffic, water pollution, and fire spread.

In general, the ideal state transition function reflects the state of the neighboring cells so that the state transition occurs. However, in the embodiment of FIG. 12, not only the state of the neighboring cells but also topographic information and external factors (weather conditions such as weather and temperature, etc.) are received as inputs, and thus the state transition may be made. That is, a more accurate prediction of the next state of a cell may be made by reflecting the characteristics of the topography in the ideal cell automata model, and furthermore, real-time weather information.

In this case, the state transition function according to the embodiment of the present invention is not the same for each cell and does not change over time as in the conventional method, but varies according to the change in the location of the cell and the change in time, and the state transition rule is not deterministic and may have uncertainty. When the state transition function is obtained using the domain knowledge as before, validation is required, but when the state transition function is obtained through machine learning of big data, the problem of validation may be solved because it is based on real data.

For example, the state variable s(t′, i, j), in which the state variable s(t, i, j) is updated after a certain time elapses, may be affected from s(t, i, j−1), s(t, i−1, j), s(t, i+1, j), and s(t, i, j+1) which are state variables of cell/node (i, j) and adjacent cells/nodes (i, j−1), (i−1, j), (i+1, j), and (i, j+1).

In this case, the correlation parameters between the state variables s(t′, i, j) and s(t, i, j) updated after a certain time elapses and the state variables s(t, i, j−1), s(t, i−1, j), s(t, i+1, j), and s(t, i, j+1) of the adjacent cells/nodes may be set as parameters of the theory-driven model describing the target system of FIG. 12. Meanwhile, s(t″, i, j), which is the next state of the state variable s(t′, i, j), may be obtained through the state variable s(t′, i, j) and the state variables s(t′, i, j−1), s(t′, i−1, j), s(t′, i+1, j), and s(t′, i, j+1) of the adjacent cells/nodes and the parameters of the theory-driven model. In this case, the state transition function may be modeled by combining the theory-driven model and the data-driven model as described above.

FIG. 12 illustrates that only the cells/nodes directly adjacent in space affect the next state, but this is only an example, and according to the physical laws, various patterns that affect the state change of each node according to spatial distribution and the passage of time may exist. Such a pattern may be defined by the laws of physics, or may be searched for by a process such as machine learning.

In addition, FIG. 12 illustrates an embodiment in which each node is defined according to the spatial distribution and the state information of the node is updated over time, but the spirit of the present invention is not limited thereto, and in the theory-driven model, each node may be divided and defined by at least one of the spatial distribution and/or the passage of time, and the state change of each node may be updated and tracked by at least one of the spatial distribution and/or the passage of time.

An example of the state information indicated by each node according to the spatial distribution in FIG. 12 may include a spread of a forest fire, a spread of fire in a building, a flooding status of a specific region, and a flooding status by region of above-ground/underground facilities (e.g., subway stations, tunnels, etc.), etc. In addition, in an application such as a cybercity, information on a current status of traffic flow, whether or not a traffic jam occurs, or the like in an entire region or a partial region of the city may be displayed. Based on such state information, various service models such as intelligent evacuation route guidance and optimized movement route guidance in the current situation may be derived by applying the theory-driven model, a digital twin model, and a virtual sensor model of the present invention.

In addition, when used in an industrial site, nodes may be each production facility in a production line or each part in the production facility, the state information may be data such as vibration, heat generation, and noise, and information that may be determined through the data may include information such as whether or not an abnormality has occurred in the production facility, the locations of the production facilities or parts where the abnormality occurred, and the degree of abnormality.

When the theory-driven model of the present invention is applied to the medical or biological field, the target system for analyzing and predicting the occurrence, spread, or healing process of a disease may be constructed. In this case, the target system that the theory-driven model may model may include cells, blood vessels, a composition of a skeleton, a composition of organs, blood flow, or the like. For example, when simulating blood flow in a blood vessel, the parameters (parameters to be described) included in the target system may include at least one of fractional flow reserve (FFR), wall stress shear (WSS), blood flow velocity, and vascular wall stress. In this case, the fractional flow reserve (FFR) is a ratio of a maximum blood flow of distal and proximal normal blood vessels of a coronary artery stenosis site.

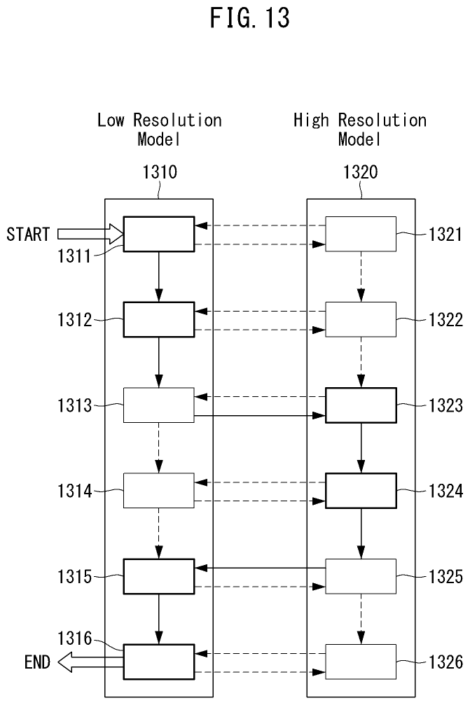

FIG. 13 is a diagram illustrating an example of a target system to which a multi-resolution model is applied as a target system to be described by a system model according to an embodiment of the present invention.

In the process of digitizing and modeling the target system, a multiple resolution model technique is used as a means of increasing the accuracy and the efficiency of modeling. Examples of using a multi-resolution model for traffic flow simulation may include Korean Patent KR 10-0969481 “Traffic flow simulation device and traffic flow simulation system including the same” and KR 10-1815511 “Framework for traffic simulation and simulation method using the same,” and examples of applying a multi-resolution model to fluid particle simulation may include Korean Patent KR 10-0872434 “Multi-resolution fluid particle simulation system and method.” The multi-resolution models are generally simulated by applying different resolutions for each region, and are used to achieve high-resolution simulations using limited computational resources. In the traffic flow simulation, it is often named a microscopic/micro model, a mesoscopic/meso model, and a macroscopic/macro model, and a hybrid resolution model in which these are combined is also used.

The recent development of technologies such as the Internet of Things (IoT) provides an infrastructure in which it is easy to collect various types of data, and even in simulation technology using a multi-resolution model, there is a growing demand to improve the performance of modeling and simulation (M&S) by effectively utilizing big data obtained by IoT infrastructure by using the effective combination of the data-driven model and the physical-driven model.

In the related art, the multi-resolution modeling technique is treated only as a concept for applying different resolutions for each spatial region. However, adjacent spatial regions are not completely separated objects, but have a close correlation with each other and influence each other. Accordingly, when different resolutions are applied to adjacent spatial regions, a problem arises as to how to convert different resolutions between adjacent spatial regions. In particular, with the recent development of the Internet of Things (IoT) and sensor technology, precise data is collected for each spatial region, and it is difficult to accurately model and simulate the target system without considering the correlations within this data.

An embodiment of the present invention is an invention derived to solve the problems of the related art, and describes resolution conversion between adjacent spatial regions using the cell automata technique, and in this process, may solve the transition between different resolution models of each cell due to the influence of adjacent cells by applying the data-driven model, or by applying a hybrid model of the data-driven model and the theory-driven model.

In this case, although it has been described as multi-resolution for convenience of description, a case in which not only resolution but also fidelity is different may be included in the equivalent range. The resolution is defined as “the degree of detail and precision used in the representation of real world aspects in a model or simulation” according to Simulation Interoperability Standards Organization/Simulation Interoperability Workshop (SISO/SIW), and the fidelity is defined as “the degree to which the representation within a simulation is similar to a real world feature or condition in a measurable or perceivable manner.”

Referring to FIG. 13, a low-resolution model 1310 and a high-resolution model 1320 are illustrated. The low-resolution model 1310 may include regionally divided regional low-resolution models 1311, 1312, 1313, 1314, 1315, and 1316, and the high-resolution model 1320 may include regionally divided regional high-resolution models 1321, 1322, 1323, 1324, 1325, and 1326.

A simulation model of macroscopic, mesoscopic or microscopic resolution may be created according to the purpose required in the traffic simulation. Depending on the performance or effect index (scale) to be obtained through simulation, the type of object included in the model or the level of description may also vary. In order to properly respond to various analysis needs for traffic-related problems, it is possible to construct a simulation system suitable for the purpose by flexibly synthesizing unit regional models describing component objects. In this case, a technique for determining the resolution applied to each region according to a given condition is a known technique, and is known from Korean Patent KR 10-1815511 and the like. Since applying the high-resolution model when the low resolution is sufficient may lead to waste of memory and computing power, it is necessary to determine an appropriate resolution for each region for efficient operation.

For convenience of description, it is assumed that the simulation starts from the regional low-resolution model 1311. In this case, first and second regional low-resolution models 1311 and 1312 may be applied to the first region and the second region. Thereafter, it may be determined that a third regional high-resolution model 1323 is applied to the third region by using conventional techniques and various known techniques. In this case, the simulation that has already been performed may activate a third regional low-resolution model 1313 from the first and second regional low-resolution models 1311 and 1312. It is necessary to acquire the third regional high-resolution model 1323 for the third region from the dataset at this time. Since this process is a process of subdividing the resolution, it may be named disaggregation.

It may be determined that a fourth region high-resolution model 1324 is also applied to the fourth region by the above-described conventional techniques and various well-known techniques. Thereafter, it may be determined that a fifth regional low-resolution model 1315 is applied to the fifth region. In this case, the simulation that has already been performed may activate a fifth regional high-resolution model 1325 for the fifth region from the third and fourth regional high-resolution models 1323 and 1324. It is necessary to acquire the fifth regional low-resolution model 1315 for the fifth region from the dataset at this time. Since this process is a process of lowering the resolution, it may be named aggregation.

Thereafter, the simulation may be ended by activating a sixth regional low-resolution model 1316 from the fifth regional low-resolution model 1315.

FIG. 13 illustrates an embodiment of a case in which the regional low-resolution models 1311, 1312, 1313, 1314, 1315, and 1316 and the regional high-resolution models 1321, 1322, 1323, 1324, 1325, and 1326 are predefined for each region, but the spirit of the present invention is not limited to this embodiment, and it will be understood by those skilled in the art that a model having a resolution required for each region may be adaptively generated.

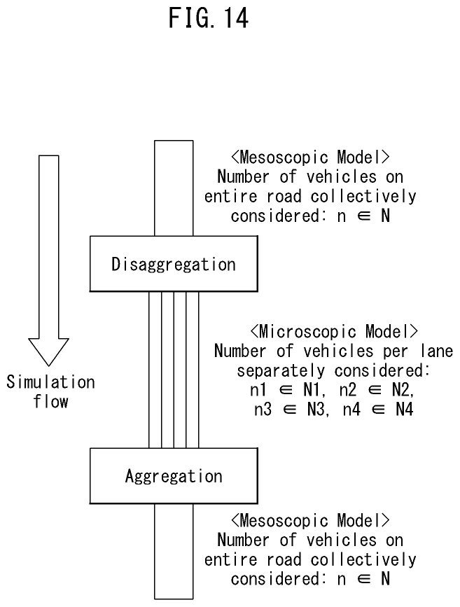

FIG. 14 is a diagram illustrating an example of a case in which traffic flow is described by applying a multi-resolution model as the target system to be described by the system model according to the embodiment of the present invention.

An example in which a mesoscopic model is applied as a low-resolution model and a microscopic model is applied as a high-resolution model is assumed. For example, the microscopic model may be applied to road regions around an intersection, and the mesoscopic model may be applied to other road regions.

In this case, according to the simulation flow, the mesoscopic model is applied to a region far from an intersection, and in this case, the number of vehicles on the entire road traveling in the same direction may be collectively considered. n, which is an element of a set N, may be acquired as data in a corresponding region. When entering the region around the intersection, the microscopic model is applied. In this case, the number of vehicles per lane traveling in the same direction may be separately considered. Assuming that there are four lanes, elements n1, n2, n3, and n4 of the sets N1, N2, N3, and N4 for each lane may be acquired as data in the corresponding region. According to the simulation flow, the disaggregation is a process of acquiring data n1, n2, n3, and n4 based on data n, and the aggregation is a process of acquiring data n based on data n1, n2, n3, and n4.

In this case, data n1, n2, n3, and n4 may correspond to the number and speed of vehicles in each lane traveling in the same direction, and data n may be the number and average speed of vehicles in all lanes traveling in the same direction. Each region may be meshed or segmented per unit length, for example 10 meters, 20 meters, or 100 meters, and the speed, average speed, maximum/minimum speed, etc., of vehicle within the section may be given as data and parameters.

In the case of the aggregation, for example, the number of vehicles may be given by n=n1+n2+n3+n4, and therefore the required calculation is not complicated. Compared to the case where the data set given by the high-resolution model is N1×N2×N3×N4, the data set given by the low-resolution model is simplified to N, and therefore there is no difficulty in calculation. In this case, it is assumed that information loss occurs as the data set or parameters are simplified, but the loss of information is not a problem if there is no major problem in achieving the purpose of the simulation.

In the disaggregation, since it is necessary to obtain N1×N2×N3×N4 from the simplified data and parameter set N, additional information is required in addition to the given low-resolution data and parameter set N. For this, various types of situation information may be given as additional information. For example, information on location (which may be classified according to a traveling direction (straight/left turn/right turn) of a lane), time zone (commuting time, normal time zone, late night), date (weekday, weekend, holiday, consecutive holidays), season, weather (sunny, snow/rain, typhoon, yellow dust, fine dust), and regulatory information (traffic control or accident occurrence) may be given.

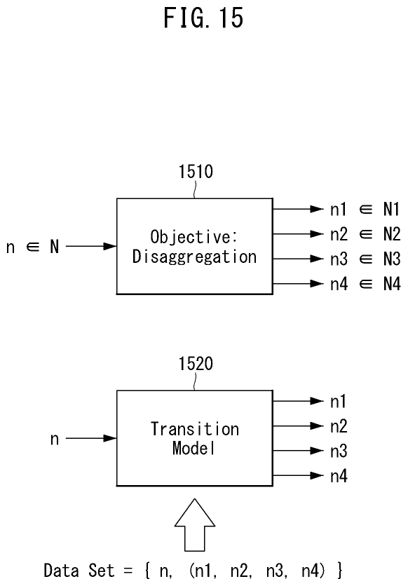

FIG. 15 is a diagram illustrating disaggregation transition of data in a transition model and a multi-resolution model to be described by the transition model according to an embodiment of the present invention.

Referring to FIG. 15, a data transition for disaggregation is defined as a target 1510 to be described, and a transition model 1520 for identifying a target 1510 is proposed. The transition model 1520 may model a data transition process for disaggregation by training based on the big data set {n, (n1, n2, n3, n4)}.

In this case, the transition model 1520 may be implemented as a data-driven model that is one single black box, and may be implemented by a hybrid system model in which the data-driven model and the theory-driven model according to the embodiments of FIGS. 1 to 11 described above are combined. For example, there are physical laws or operating rules that are naturally applied, such as a conservation law that vehicles entering and exiting a region divided into cells should be the same. The minimum structural information of the transition model 1520 may be defined by these physical laws or behavior/operation rules, the transition model 1520 may have sub-models internally based on the structural information, and the sub-models may be implemented as the data-driven model. When the complex data-driven model based on the structural information is applied to the transition model 1520, it has the same effect as if the actual measurement data verification that the theory-driven model should necessarily go through had already been done while providing explainable predictability, and thus the reliability of the simulation may be increased.

FIGS. 14 and 15 illustrate an embodiment in which a transition is made with respect to a data set, but the spirit of the present invention is not limited thereto. For example, as the data set and various parameters obtained from the data set, a regional model including all parameters capable of describing a traffic flow may be defined based on a resolution given for each region. By applying the data-driven model and the hybrid model illustrated in FIGS. 14 and 15, a transition between resolution-based models for each region defined for each region may be modeled as a transition model.

Referring to FIGS. 12 to 15 together, although the third regional high-resolution model 1323 is desired to be applied to the third region of FIG. 13, when the cell automata technique of FIG. 12 is applied to the second regional low-resolution model 1312 of a second region adjacent in the simulation flow, the third regional low-resolution model 1313 may be easily activated. In this case, a process of acquiring the third regional high-resolution model 1323 based on the third regional low-resolution model 1313 may be described using the transition model 1520 illustrated in FIGS. 14 and 15. When the third regional low-resolution model 1313, which is a low first resolution-based model, is obtained in the third region, and the third regional high-resolution model 1323, which is a high second resolution-based model, is obtained based on the third regional low-resolution model 1313, the transition model 1520 of FIGS. 14 and 15 may be applied.

The present invention may provide a system model capable of modeling a causal relationship between multiple causes and results that describe a target system, and integrally describing the entire target system by combining sub-models that partially describe the target system. In this case, a combining relationship and/or a data connection relationship between sub-models in the system model is defined based on structural information, and the structural information may be acquired using knowledge about the target system.

The present invention may provide a hybrid model that operates by combining the advantages of a physical-driven model and a data-driven model, and provides a system modeling technique capable of applying a hybrid model to a system model described by a complex model by extending a field of application of the hybrid model.

The present invention may provide a cooperative, not competing with each other, alternative capable of overcoming limitations of each approach by complementarily utilizing advantages of two modeling methods, a physical-driven model and a data-driven model, to enable robust analysis/prediction support. In this case, unlike the related arts in which the physical-driven model or the data-driven model is selectively applied, the present invention may provide a technique capable of implementing a complex model by combining the physical-driven model and the data-driven model more robustly.

The present invention may provide a system model capable of using accuracy of a data-driven model, but inferring data outside (out of) a data range which is a limitation of the data-driven model.

The present invention may provide a system model capable of describing a behavior or state of a target system due to complex causes using a data-driven model, and that generates descriptive information that may explain a correlation between data in a data-driven model based on structural information.

The present invention may provide a system model capable of applying normative analysis using a data-driven model, which was difficult to implement with a data-driven model before.

According to the present invention, a hybrid model that may combine advantages of a data-driven model and a physical-driven model is implemented as a complex system model, and the complex system model may be applied to a digital twin for describing a highly complex target system.

According to the present invention, a system model with a built-in data-driven model embeds machine learning content using data acquired through operation and observation of a target system, and as a result, in a domain of the acquired data, the model itself becomes a verified model, and it is possible to overcome limitations that can be faced when analyzing or predicting the target system using only a data-driven model or only a physical-driven model.

By embedding machine learning in the system model, it is possible to reduce a degree of prior knowledge required for a target system, achieve an effect of model validation (verification with real data), and analyze and predict a behavior of the target system according to a change in a structure/rule in the target system which can not be done only with machine learning.

The present invention can have the following advantages compared to an existing data-driven model. In general, a data-driven model shows very high accuracy for static data, but it is known that it is not easy to apply a data-driven model to dynamic analysis where variables that affect the operation are various. According to the present invention, a data-driven model can also be applied to a target system having a space variant, a time variant, and a stochastic feature.

In addition, according to the present invention, it is possible to reflect non-linear features of the target system. Since many systems in the real world have non-linear features without a superposition theory between input and output, it is a great advantage for a state transition function to be able to consider the non-linear features. In addition, additional situation information such as weather conditions can be expressed through data acquired from the real system, and thus the data-driven model can be applied as a modeling technique robust to the implementation of complex digital models such as a digital twin model that mimics the real world.

The present invention was derived from the research conducted as part of the Technology Transfer Commercialization Project of the Korean Ministry of Science and ICT and the Korea Innovation Foundation [task management number: 2019-DD-RD-0056-01-101; task name: Machine Learning-Embedded Digital Twin Modeling Simulation Platform Development].

The present invention was derived from the research conducted as part of the Ministry of SMEs and Startups and Jeju Regional Business Evaluation Group's innovative growth support (R&D) project for local businesses [task management number: P0010175; task name: BAS-based Digital Twin Platform Core SW and Application Model Development].

A method of operation and/or training the system model and/or the transfer model executed by at least one processor included in a computing system according to an embodiment of the present invention may be implemented in the form of program instructions executable by a variety of computing means and then stored in a computer-readable storage medium. The computer-readable storage medium may include program instructions, data files, and data structures solely or in combination. Program instructions recorded in the storage medium may have been specially designed and configured for the present invention, or may be known to or available to those who have ordinary knowledge in the field of computer software. Examples of the computer-readable storage medium include all types of hardware devices specially configured to record and execute program instructions, such as magnetic media, such as a hard disk, a floppy disk, and magnetic tape, optical media, such as compact disk (CD)-read only memory (ROM) and a digital versatile disk (DVD), magneto-optical media, such as a floptical disk, ROM, random access memory (RAM), and flash memory. Examples of the program instructions include machine code, such as code created by a compiler, and high-level language code executable by a computer using an interpreter. These hardware devices may be configured to operate as one or more software modules in order to perform the operation of the present invention, and the vice versa.

However, the present invention is not limited to the embodiments. Like reference symbols in the drawings designate like components. The lengths, heights, sizes, widths, etc. introduced in the embodiments and drawings of the present invention may be exaggerated to help to understand the present invention.

Although the present invention has been described with reference to specific details such as the specific components, and the limited embodiments and drawings, these are provided merely to help a general understanding of the present invention, and the present invention is not limited thereto. Furthermore, those having ordinary skill in the art to which the present invention pertains may make various modifications and variations from the above detailed description.

Therefore, the spirit of the present invention should not be defined based only on the described embodiments, and not only the attached claims but also all equivalents to the claims should be construed as falling within the scope of the spirit of the present invention.

What is claimed is:

1. A computing system for implementing and operating a model describing a target system, the computing system comprising:
a communication interface configured to receive or require acquired data about the target system;
a system model including a plurality of sub-models; and
at least one processor,
wherein each of the plurality of sub-models is a model capable of inferring or predicting at least a part of the acquired data as output data when receiving another part of the acquired data as input data,
wherein a data connection relation between the input data and the output data of each of the plurality of sub-models in the system model is defined based on structural information of the target system, and
wherein the at least one processor is configured to:
select first data as input data of a first sub-module, based on the structural information, from among new input data for the target system;
provide second data as input data of a second sub-module, based on the structural information, wherein the second sub-module is defined to receive output data of the first sub-module as input data thereof by the structural information;
control the second sub-model to infer a behavior of the target system based on the second data; and
provide third data based on output data of the second sub-module as an output of the system model describing the behavior of the target system.

2. The computing system of claim 1, wherein the at least one processor is further configured to select the second data as the input data of the second sub-module, based on the structural information, among the new input data for the target system.

3. The computing system of claim 1, wherein the at least one processor is further configured to:
control the first sub-model to infer the behavior of the target system based on the first data; and
provide the second data using output data from the first sub-module with inference of the first sub-module based on the structural information as the input data of the second sub-module.

4. The computing system of claim 1, wherein each of the plurality of sub-models is at least one of a theory-driven model capable of deductive reasoning and is defined based on obtainable domain knowledge, experience, and theory that are related to the target system, a data-driven model trained based on the acquired data about the target system, and a complex model formed by combining the theory-driven model and the data-driven model to be complementary to each other.

5. The computing system of claim 1, wherein the structural information is defined based on a data connection relation between parameters of a theory-driven primitive model included in the target system and acquired using knowledge about the target system, and whether each of the parameters is included in the acquired data.

6. The computing system of claim 1, wherein the structural information includes:
information on a first parameter selected as at least one of the input data and the output data of each of the plurality of sub-models from among parameters of a theory-driven primitive model included in the target system and acquired using knowledge about the target system; and
sub-model data structure information wherein the first parameter is defined as the input data and output data of each of the plurality of sub-models with respect to the theory-driven primitive model.

7. The computing system of claim 1, further comprising:
a user interface configured to receive a user query about the target system and transmit the received user query to the at least one processor,
wherein the at least one processor is further configured to interpret the user query into an instruction command that is executed within the computing system.

8. The computing system of claim 7, wherein the at least one processor is further configured to:
search for at least one of a condition variable, a control variable, and a design variable of the target system corresponding to an association of at least two of the first data, the second data, and the third data based on the structural information and the data connection relation when the user query includes a query for the association of at least two or more of the first data, the second data, and the third data, to generate a search result;
generate a response to the user query based on the search result; and
transmit the response to the user query to the user interface.

9. The computing system of claim 7, wherein, when the user query includes a prediction of the behavior of the target system when the second data is out of an acquired data domain covered by the acquired data, the at least one processor is further configured to:
apply at least one of a theory-driven model capable of deductive reasoning, a data-driven model trained based on the acquired data, and a complex model formed by combining the theory-driven model and the data-driven model to be complementary to each other as the second sub-model.

10. The computing system of claim 9, wherein, when the user query includes a request in which a distribution of the third data is to be adjusted, the at least one processor is further configured to:
generate a first distribution applicable to the first data, a second distribution of the second data related to the first distribution, and a third distribution of the third data related to the second distribution among the acquired data based on the structural information and the system model; and
provide at least one of a limiting condition of a range of the first distribution in response to the user query based on the first distribution, the second distribution, the third distribution, and the structural information, and a modified condition suggesting a change of at least one of a condition variable, a control variable, or a design variable of the target system to the user.

11. A computing system for implementing and operating a model describing a target system, the computing system comprising:
a communication interface configured to receive or require acquired data about the target system;
a system model including a plurality of sub-models; and
at least one processor,
wherein each of the plurality of sub-models is a model trained to infer or predict at least a part of the acquired data as output data when receiving another part of the acquired data as input data,
wherein a data connection relation between the input data and the output data of each of the plurality of sub-models in the system model is defined based on structural information of the target system, and
wherein the at least one processor is configured to:
provide first data for a training of a first sub-module, based on the structural information, from among the acquired data;
provide second data for the training of the first sub-module and for a training of second sub-module, based on the structural information, from among the acquired data, wherein the second sub-module is defined to receive output data of the first sub-module as input data thereof by the structural information; and
provide third data for the training of the second sub-module, based on the structural information.

12. The computing system of claim 11, wherein the at least one processor is further configured to control the first sub-module to learn a relation between the first data and the second data.

13. The computing system of claim 11, wherein the at least one processor is further configured to control the second sub-module to learn a relation between the second data and the third data.

14. The computing system of claim 11, wherein each of the plurality of sub-models is at least one of a theory-driven model capable of deductive reasoning and is defined based on obtainable domain knowledge, experience, and theory that are related to the target system, a data-driven model trained based on the acquired data about the target system, and a complex model formed by combining the theory-driven model and the data-driven model to be complementary to each other.

15. A method of operating a system model describing a target system, executed by at least one processor of a computing system implementing and operating the system model, the method comprising:
receiving or requiring, by a communication interface, acquired data about the target system;
providing, by the at least one processor, first data from among the acquired data as input data of a first sub-model included in the system model, based on structural information;
providing, by the at least one processor, second data from among the acquired data as input data of a second sub-model included in the system model, based on the structural information, wherein the second sub-module is defined to receive output data of the first sub-module as input data thereof by the structural information;
controlling, by the at least one processor, the second sub-model to infer a behavior of the target system based on the second data; and
providing, by the at least one processor, third data based on output data of the second sub-module as an output of the system model describing the behavior of the target system.

16. The method of claim 15, further comprising:
searching for, by the at least on processor, at least one of a condition variable, a control variable, and a design variable of the target system corresponding to an association of at least two of the first data, the second data, and the third data based on the structural information when a user query includes a query for the association of at least two or more of the first data, the second data, and the third data, to generate a search result;
generating, by the at least on processor, a response to the user query based on the search result; and
transmitting, by the at least on processor, the response to the user query to a user interface.

17. The method of claim 15, wherein, when a user query includes a prediction of the behavior of the target system when the second data is out of an acquired data domain covered by the acquired data, further comprising:
applying, by the at least on processor, at least one of a theory-driven model capable of deductive reasoning, a data-driven model trained based on the acquired data, and a complex model formed by combining the theory-driven model and the data-driven model to be complementary to each other as the second sub-model

18. The method of claim 15, wherein, when a user query includes a request in which a distribution of the third data is to be adjusted, further comprising:
generating, by the at least on processor, a first distribution applicable to the first data, a second distribution of the second data related to the first distribution, and a third distribution of the third data related to the second distribution among the acquired data based on the structural information and the system model; and
providing, by the at least on processor, at least one of a limiting condition of a range of the first distribution in response to the user query based on the first distribution, the second distribution, the third distribution, and the structural information, and a modified condition suggesting a change of at least one of a condition variable, a control variable, or a design variable of the target system to a user.

19. A method of training a system model describing a target system, executed by at least one processor of a computing system implementing and operating the system model, the method comprising:
receiving or requiring, by a communication interface, acquired data about the target system;
providing, by the at least on processor, first data for a training of a first sub-module, based on structural information, from among the acquired data;
providing, by the at least on processor, second data for the training of the first sub-module and for a training of second sub-module, based on the structural information, from among the acquired data, wherein the second sub-module is defined to receive output data of the first sub-module as input data thereof by the structural information; and
providing, by the at least on processor, third data for the training of the second sub-module, based on the structural information.
